(19) United States
(12) Patent Application Publication
(10) Pub. No.: US 2026/0182383 A1
(43) Pub. Date: Jun. 25, 2026

(54) PACKAGE COMPRISING AN INTEGRATED DEVICE AND A PASSIVE DEVICE WITH VERTICALLY ALIGNED METAL LAYERS

(71) Applicant: QUALCOMM Incorporated, San Diego, CA (US)

(72) Inventors: Jiaping ZHANG, San Diego, CA (US); Anirudh BHAT, San Diego, CA (US); Heun Gun SHIN, San Diego, CA (US); Tsu-Wei LIN, San Diego, CA (US)

(21) Appl. No.: 18/988,436

(22) Filed: Dec. 19, 2024

(51) Int. Cl. H01L 23/552; H01L 23/00; H01L 23/538; H01L 25/18; H10D 1/20

(52) U.S. Cl. CPC H10W 42/20; H10D 1/20; H10W 90/00; H10W 70/611; H10W 70/635; H10W 90/724

(57) ABSTRACT

A package comprising a substrate comprising a plurality of substrate interconnects, wherein some substrate interconnects from the substrate interconnects are located on at least one substrate metal layer; an integrated device coupled to the substrate; and a passive device coupled to the substrate, wherein the passive device comprises at least one dielectric layer; and a plurality of interconnects, wherein the plurality of interconnects comprise a first plurality of interconnects that are located on a plurality of metal layers, and wherein the plurality of metal layers are aligned in a direction that is orthogonal to the at least one substrate metal layer of the substrate; and an encapsulation layer that at least partially encapsulates the integrated device and the passive device.

### FIELD

Various features relate to packages with integrated devices and passive devices.

### BACKGROUND

A package may include a substrate and integrated devices. These components are coupled together to provide a package that may perform various electrical functions. There is an ongoing need to provide better performing packages. Moreover, there is also an ongoing need to reduce and/or minimize the overall size of the packages.

### SUMMARY

Various features relate to packages with integrated devices and passive devices.

One example provides a package comprising a substrate comprising a plurality of substrate interconnects, wherein some substrate interconnects from the substrate interconnects are located on at least one substrate metal layer; an integrated device coupled to the substrate; and a passive device coupled to the substrate, wherein the passive device comprises at least one dielectric layer; and a plurality of interconnects, wherein the plurality of interconnects comprise a first plurality of interconnects that are located on a plurality of metal layers, and wherein the plurality of metal layers are aligned in a direction that is orthogonal to the at least one substrate metal layer of the substrate; and an encapsulation layer that at least partially encapsulates the integrated device and the passive device.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates an exemplary cross sectional profile view of a package that includes an integrated device and a passive device with vertically aligned interconnects.

FIG. 2 illustrates an exemplary cross sectional profile view of a passive device with vertically aligned interconnects.

FIG. 3 illustrates an exemplary cross sectional profile view of a passive device with vertically aligned interconnects.

FIG. 4 illustrates an exemplary view of a passive device with vertically aligned interconnects.

FIG. 5 illustrates an exemplary view of passive devices with vertically aligned interconnects.

FIG. 6 illustrates an exemplary view of a package that includes an integrated device and a passive device with vertically aligned interconnects.

FIG. 7 illustrates an exemplary cross sectional profile view of a package that includes an integrated device and a passive device with vertically aligned interconnects.

FIG. 8 illustrates an exemplary sequence for fabricating a passive device with vertically aligned interconnects.

FIGS. 9A-9C illustrate an exemplary sequence for fabricating a package that includes an integrated device and a passive device with vertically aligned interconnects

FIG. 10 illustrates an exemplary flow chart of a method for fabricating a package that includes an integrated device and a passive device with vertically aligned interconnects.

FIGS. 11A-11C illustrate an exemplary sequence for fabricating a substrate.

FIG. 12 illustrates an exemplary flow chart of a method for fabricating a substrate.

FIG. 13 illustrates various electronic devices that may integrate a die, an electronic circuit, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown as block diagrams in order to avoid obscuring the aspects in unnecessary detail. In other instances, well-known circuits, structures and techniques may not be shown in detail in order not to obscure the aspects of the disclosure.

The present disclosure describes a package comprising a substrate comprising a plurality of substrate interconnects, wherein some substrate interconnects from the substrate interconnects are located on at least one substrate metal layer; an integrated device coupled to the substrate; and a passive device coupled to the substrate, wherein the passive device comprises at least one dielectric layer; and a plurality of interconnects, wherein the plurality of interconnects comprise a first plurality of interconnects that are located on a plurality of metal layers, and wherein the plurality of metal layers are aligned in a direction that is orthogonal to the at least one substrate metal layer of the substrate; and an encapsulation layer that at least partially encapsulates the integrated device and the passive device. The package provides a substrate that include inductors that have improved performance, including improved inductance, which can lead to improved performance of the package.

### Exemplary Package Comprising an Integrated Device and a Passive Device with Vertically Aligned Interconnects

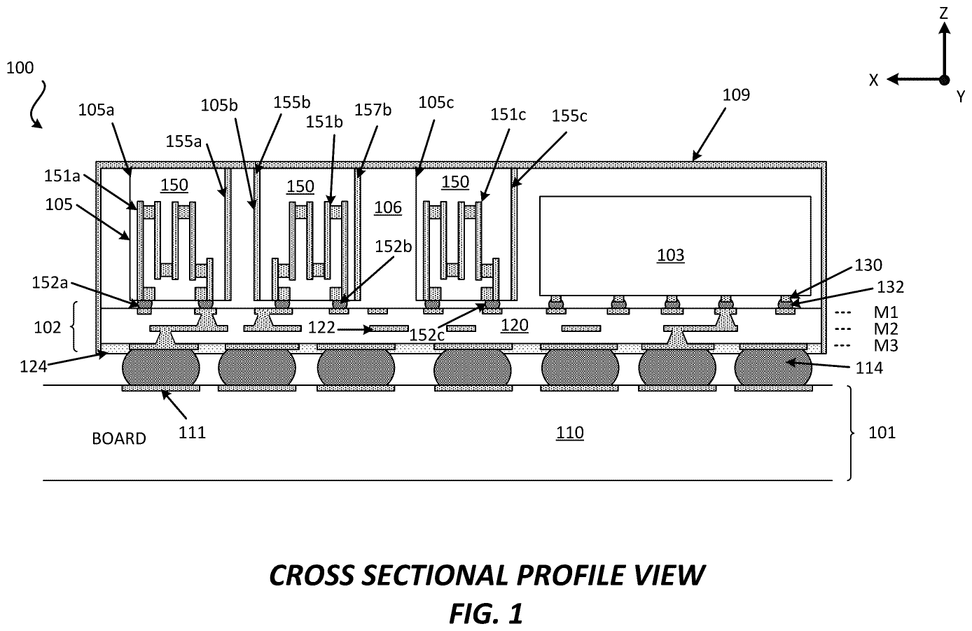

FIG. 1 illustrates a cross sectional profile view of a package 100 that includes a passive device with vertically aligned metal layers and/or vertically aligned interconnects (e.g., vertically aligned trace interconnects and/or vertically aligned pad interconnects). The package 100 is coupled to a board 101 through a plurality of solder interconnects 114. The board 101 includes at least one board dielectric layer 110 and a plurality of board interconnects 112. The board 101 may include a printed circuit board (PCB). In some implementations, the package 100 may be coupled to a substrate instead of the board 101.

The package 100 includes a substrate 102, an integrated device 103, a plurality of passive devices 105, an encapsulation layer 106 and a metal layer 109. The plurality of passive devices 105 includes a passive device 105a, a passive device 105b and a passive device 105c. The passive device 105a may be configured as an inductor device. The passive device 105b may be configured as an inductor device. The passive device 105c may be configured as an inductor device.

The substrate 102 may be a laminated substrate (e.g., coreless substrate, cored substrate). The substrate 102 includes at least one dielectric layer 120, a plurality of interconnects 122 and a solder resist layer 124. The plurality of interconnects 122 may include a plurality of substrate interconnects (e.g., substrate trace interconnects, substrate pad interconnects, substrate via interconnects). Some of the interconnects from the plurality of interconnects 122 may be located on at least one metal layer (e.g., substrate metal layer) of the substrate 102. Substrate via interconnects of the plurality of interconnects 122, by definition, are not located on a metal layer of the substrate 102. Substrate via interconnects may be located between metal layers of the substrate 102. As shown in FIG. 1, the substrate 102 includes 3 substrate metal layers (e.g., M1, M2, M3). However, different implementations may have different numbers of substrate metal layers. As shown in FIG. 1. the substrate metal layers of the substrate 102 may be aligned in the X direction and/or the Y direction. The substrate metal layers of the substrate 102 may be aligned in a horizontal direction. The substrate metal layers of the substrate 102 may be located on an X-Y plane and/or parallel to an X-Y plane. Interconnects, such as substrate trace interconnects and/or substrate pad interconnects, that are located on the substrate metal layers of the substrate 102 may be located on an X-Y plane and/or parallel to an X-Y plane.

The integrated device 103 is coupled to the substrate 102. The integrated device 103 may be coupled to the plurality of interconnects 122 of the substrate 102 through a plurality of pillar interconnects 130 and/or a plurality of solder interconnects 132.

The passive device 105a is coupled to the substrate 102. The passive device 105a may be coupled to the plurality of interconnects 122 of the substrate 102 through a plurality of solder interconnects 152a. The passive device 105a includes at least one dielectric layer 150 and a plurality of interconnects 151a. Some of the interconnects from the plurality of interconnects 151a are configured to operate as an inductor (e.g., solenoid inductor). The passive device 105a may include vertically aligned interconnects (e.g., vertically aligned trace interconnects and/or vertically aligned pad interconnects). The passive device 105a includes interconnects that are located on metal layers. The metal layers of the passive device 105a are aligned in the Z-direction. That is, interconnects that are located on the metal layers of the passive device 105a are aligned in the Z-direction. The metal layers of the passive device 105a may be located on the X-Z plane and/or the Y-Z plane (or parallel to the X-Z plane and/or the Y-Z plane). In some implementations, the metal layers of the passive device 105a are approximately orthogonal (e.g., approximately perpendicular) to the substrate metal layers of the substrate 102. Trace interconnects and/or pad interconnects are examples of interconnects that are located on metal layers of the passive device 105a. Via interconnects of the plurality of interconnects 151a, by definition, are not located on a metal layer of the passive device 105a. The passive device 105a include a metal layer 155a that is configured as an electromagnetic interference (EMI) shield. The metal layer 155a may be a compartmental shield that extends in the Z-direction.

The passive device 105b is coupled to the substrate 102. The passive device 105b may be coupled to the plurality of interconnects 122 of the substrate 102 through a plurality of solder interconnects 152b. The passive device 105b includes at least one dielectric layer 150 and a plurality of interconnects 151b. Some of the interconnects from the plurality of interconnects 151b are configured to operate as an inductor (e.g., solenoid inductor). The passive device 105b may include vertically aligned interconnects (e.g., vertically aligned trace interconnects and/or vertically aligned pad interconnects). The passive device 105b includes interconnects that are located on metal layers. The metal layers of the passive device 105b are aligned in the Z-direction. That is, interconnects that are located on the metal layers of the passive device 105b are aligned in the Z-direction. The metal layers of the passive device 105b may be located on the X-Z plane and/or the Y-Z plane (or parallel to the X-Z plane and/or the Y-Z plane). In some implementations, the metal layers of the passive device 105b are approximately orthogonal (e.g., approximately perpendicular) to the substrate metal layers of the substrate 102. Trace interconnects and/or pad interconnects are examples of interconnects that are located on metal layers of the passive device 105b. Via interconnects of the plurality of interconnects 151b, by definition, are not located on a metal layer of the passive device 105b. The passive device 105b include a first metal layer 155b that is configured as an electromagnetic interference (EMI) shield and a second metal layer 157b that is configured as an electromagnetic interference (EMI) shield. The first metal layer 155b may be a first compartmental shield that extends in the Z-direction. The second metal layer 157b may be a second compartmental shield that extends in the Z-direction. The first metal layer 155b is located on the side of the passive device 105b that is adjacent to the passive device 105a. The second metal layer 157b is located on the side of the passive device 105b that is adjacent to the passive device 105c.

The passive device 105c is coupled to the substrate 102. The passive device 105c may be coupled to the plurality of interconnects 122 of the substrate 102 through a plurality of solder interconnects 152c. The passive device 105c includes at least one dielectric layer 150 and a plurality of interconnects 151c. Some of the interconnects from the plurality of interconnects 151c are configured to operate as an inductor (e.g., solenoid inductor). The passive device 105c may include vertically aligned interconnects (e.g., vertically aligned trace interconnects and/or vertically aligned pad interconnects). The passive device 105c includes interconnects that are located on metal layers. The metal layers of the passive device 105c are aligned in the Z-direction. That is, interconnects that are located on the metal layers of the passive device 105c are aligned in the Z-direction. The metal layers of the passive device 105c may be located on the X-Z plane and/or the Y-Z plane (or parallel to the X-Z plane and/or the Y-Z plane). In some implementations, the metal layers of the passive device 105c are approximately orthogonal (e.g., approximately perpendicular) to the substrate metal layers of the substrate 102. Trace interconnects and/or pad interconnects are examples of interconnects that are located on metal layers of the passive device 105c. Via interconnects of the plurality of interconnects 151c, by definition, are not located on a metal layer of the passive device 105c. The passive device 105c include a metal layer 155c that is configured as an electromagnetic interference (EMI) shield. The metal layer 155c may be a compartmental shield that extends in the Z-direction. The metal layer 155c is located on the side of the passive device 105c that is adjacent to the integrated device 103.

The encapsulation layer 106 is coupled to the substrate 102. The encapsulation layer 106 may at least partially encapsulate the integrated device 103, the passive device 105a, the passive device 105b and the passive device 105c. The encapsulation layer 106 may include a mold, a resin, an epoxy and/or a filler.

The metal layer 109 is coupled to a surface of the encapsulation layer 160 and a side surface of the substrate 102. The metal layer 109 may be configured as an electromagnetic interference (EMI) shield (e.g., EMI conformal shield). The metal layer 109 may be coupled to and touch the metal layer 155a of the passive device 105a, the first metal layer 155b and the second metal layer 157b of the passive device 105b and/or the metal layer 155c of the passive device 105c.

Different implementations may have different number of passive devices. The passive devices (e.g., 105a, 105b, 105c) may have different sizes, heights, designs and/or shapes. The passive devices may have inductors with different number of windings. The passive devices may have different numbers of metal layers. The passive devices may be coupled to the substrate 102 such that the inductor is aligned in different directions.

The use of the passive devices (e.g., 105a, 105b, 105c) with vertically aligned interconnects (e.g., vertically aligned trace interconnects and/or vertically aligned pad interconnects) help provide inductors with improved inductance and quality factors. Moreover, these passive devices take up less footprint (e.g., less lateral area) than inductors with similar inductances and quality factors. That is, other inductors with similar inductances and/or quality factors have bigger footprint. The smaller footprint of these passive devices, allows these passive devices to be implemented in smaller devices. Moreover, by implementing the shield with the passive devices, it allows the shield to be placed closer to the inductors, which means a package that has compartmental shielding, that has a much smaller form factor. The compartment shielding helps reduce the coupling coefficient between inductors, which helps provide improved performance for the package. Additionally, the vertically aligned interconnects (e.g., vertically aligned trace interconnects and/or vertically aligned pad interconnects) provide a more space efficient use of the region that would normally be occupied by an encapsulation layer.

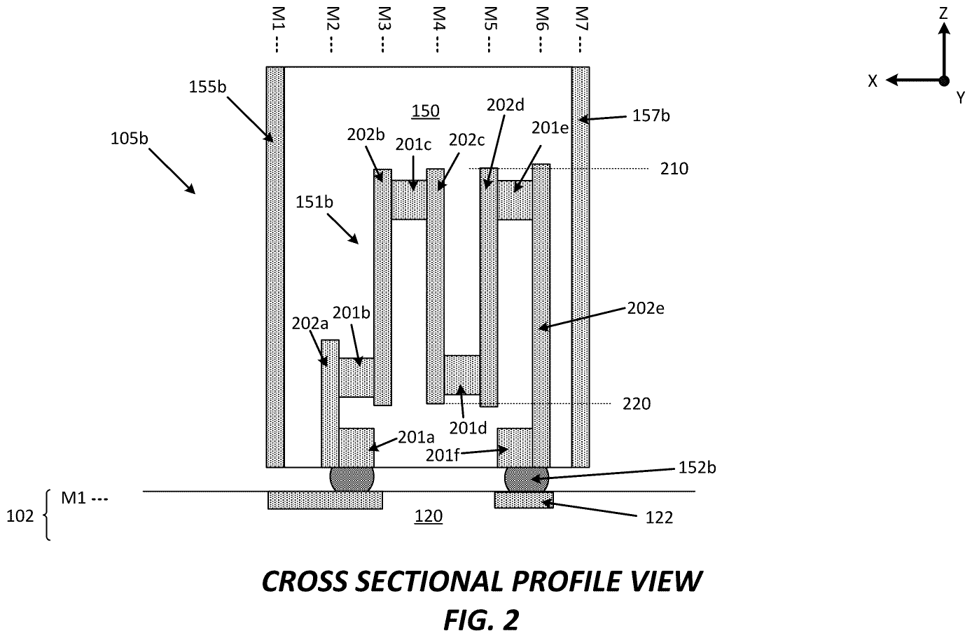

FIG. 2 illustrates a close up view of a passive device coupled to a substrate. The passive device 105b is coupled to the plurality of interconnects 122 through the plurality of solder interconnects 152b. The passive device 105b includes a plurality of interconnects 151b, a first metal layer 155b and a second metal layer 157b. The plurality of interconnects 151b may include a via interconnect 201a, an interconnect 202a, a via interconnect 201b, an interconnect 202b, a via interconnect 201c, an interconnect 202c, a via interconnect 201d, an interconnect 202d, a via interconnect 201e, an interconnect 202e and a via interconnect 201f. In some implementations, the interconnect 202a, the via interconnect 201b, the interconnect 202b, the via interconnect 201c, the interconnect 202c, the via interconnect 201d, the interconnect 202d, the via interconnect 201e, and/or the interconnect 202e may be configured as an inductor (e.g., solenoid inductor). The first metal layer 155b may be configured as a first EMI shield. The second metal layer 157b may be configured as a second EMI shield.

The via interconnect 201a is coupled to the interconnect 202a. The via interconnect 201a is coupled to the interconnect 202a and the interconnect 202b. The interconnect 202c is coupled to the via interconnect 201c and the via interconnect 201d. The interconnect 202d is coupled to the via interconnect 201d and the via interconnect 201e. The interconnect 202e is coupled to the via interconnect 201e and the via interconnect 201f. The interconnect 202a, the interconnect 202b, the interconnect 202c, the interconnect 202d and/or the interconnect 202e may include trace interconnects and/or pad interconnects. In some implementations, a solder interconnect from the plurality of solder interconnects 152b may be coupled to the via interconnect 201a and/or the interconnect 202a. In some implementations, a solder interconnect from the plurality of solder interconnects 152b may be coupled to the via interconnect 201f and/or the interconnect 202e.

The passive device 105b includes seven (7) metal layers (e.g., M1, M2, M3, M4, M5, M6, M7). Different implementations may have different numbers of metal layers. The metal layers of the passive device 105b are aligned in the Z-direction. The first metal layer 155b is located on the M1 metal layer. The interconnect 202a is located on the M2 metal layer. The interconnect 202b is located on the M3 metal layer. The interconnect 202c is located on the M4 metal layer. The interconnect 202d is located on the M5 metal layer. The interconnect 202e is located on the M6 metal layer. The second metal layer 157b is located on the M7 metal layer. As shown in FIG. 2, the metal layers of the passive device 105b are approximately orthogonal (e.g., approximately perpendicular) to the substrate metal layer of the substrate 102. For example, while the metal layers of the passive device 105b are aligned vertically (e.g., aligned along the Z direction), the substrate metal layers of the substrate 102 are aligned horizontally (e.g., aligned along the X direction and/or the Y direction). Similarly, the via interconnects (e.g., 201b, 201c, 201d, 201e) of the passive device 105b are aligned and/or extend horizontally (e.g., along the X direction and/or the Y direction), while the via interconnects of the substrate 102 are aligned and/or extend vertically (e.g., aligned along the Z direction). Thus, the via interconnects of the passive device 105b may be approximately orthogonal (e.g., approximately perpendicular) to the via interconnects of the substate 102. In some implementations, one by product of the design of the passive device 105b and the interconnects of the passive device 105b, may be that a top portion (e.g., top surface) of the interconnects that define the inductor may not all be planar to each other, as illustrated by the conceptual plane 210. In some implementations, one by product of the design of the passive device 105b and the interconnects of the passive device 105b, may be that a bottom portion (e.g., bottom surface) of the interconnects that define the inductor may not all be planar to each other, as illustrated by the conceptual plane 220. For example, a bottom surface (in the Z-direction) of the via interconnect 201d may not be planar to bottom surfaces (in the Z-direction) of the interconnect 202c and/or the interconnect 202d. In another example, a top surface (in the Z-direction) of the via interconnect 201e may not be planar to top surfaces (in the Z-direction) of the interconnect 202d and/or the interconnect 202e.

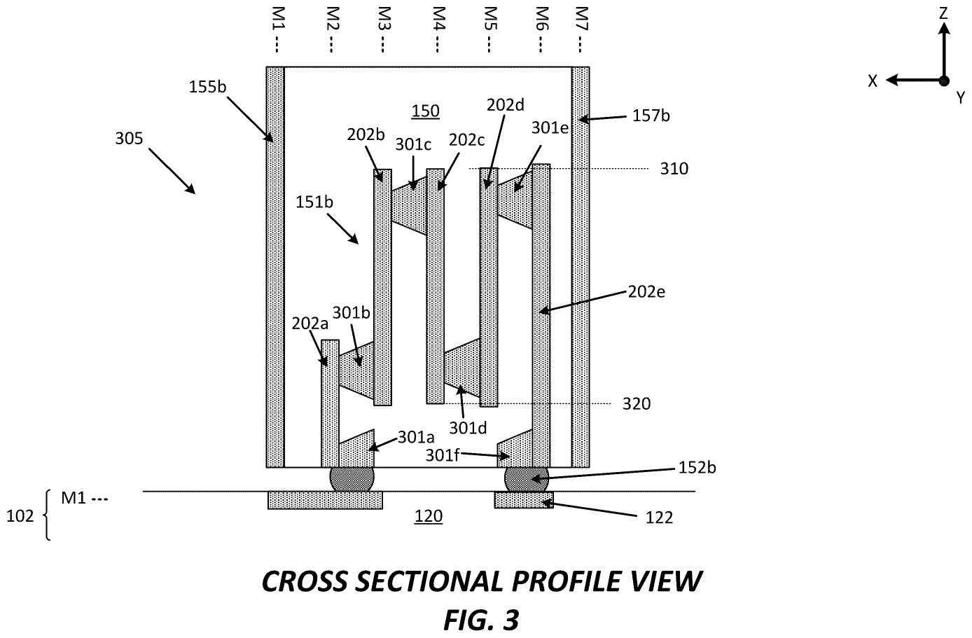

FIG. 3 illustrates a close up view of a passive device 305 coupled to a substrate. The passive device 305 is similar to the passive device 105b. However, the passive device 305 includes via interconnects that have different shapes from the via interconnects of the passive device 105b.

The passive device 305 is coupled to the plurality of interconnects 122 through the plurality of solder interconnects 152b. The passive device 105b includes a plurality of interconnects 151b, a first metal layer 155b and a second metal layer 157b. The plurality of interconnects 151b may include a via interconnect 301a, an interconnect 202a, a via interconnect 301b, an interconnect 202b, a via interconnect 301c, an interconnect 202c, a via interconnect 301d, an interconnect 202d, a via interconnect 301e, an interconnect 202e and a via interconnect 301f. In some implementations, the interconnect 202a, the via interconnect 301b, the interconnect 202b, the via interconnect 301c, the interconnect 202c, the via interconnect 301d, the interconnect 202d, the via interconnect 301e, and/or the interconnect 202e may be configured as an inductor (e.g., solenoid inductor). The first metal layer 155b may be configured as a first EMI shield. The second metal layer 157b may be configured as a second EMI shield.

The via interconnect 301a, the via interconnect 301b, the via interconnect 301c, the via interconnect 301d, the via interconnect 301e, and/or the via interconnect 301f may include a trapezoid cross section profile. The via interconnect 301a is coupled to the interconnect 202a. The via interconnect 301a is coupled to the interconnect 202a and the interconnect 202b. The interconnect 202c is coupled to the via interconnect 301c and the via interconnect 301d. The interconnect 202d is coupled to the via interconnect 301d and the via interconnect 301e. The interconnect 202e is coupled to the via interconnect 301e and the via interconnect 301f. The interconnect 202a, the interconnect 202b, the interconnect 202c, the interconnect 202d and/or the interconnect 202e may include trace interconnects and/or pad interconnects. In some implementations, a solder interconnect from the plurality of solder interconnects 152b may be coupled to the via interconnect 301a and/or the interconnect 202a. In some implementations, a solder interconnect from the plurality of solder interconnects 152b may be coupled to the via interconnect 301f and/or the interconnect 202e.

The passive device 305 includes seven (7) metal layers (e.g., M1, M2, M3, M4, M5, M6, M7). Different implementations may have different numbers of metal layers. The metal layers of the passive device 305 are aligned in the Z-direction. The first metal layer 155b is located on the M1 metal layer. The interconnect 202a is located on the M2 metal layer. The interconnect 202b is located on the M3 metal layer. The interconnect 202c is located on the M4 metal layer. The interconnect 202d is located on the M5 metal layer. The interconnect 202e is located on the M6 metal layer. The second metal layer 157b is located on the M7 metal layer. As shown in FIG. 3, the metal layers of the passive device 305 are approximately orthogonal (e.g., approximately perpendicular) to the substrate metal layer of the substrate 102. For example, while the metal layers of the passive device 305 are aligned vertically (e.g., aligned along the Z direction), the substrate metal layers of the substrate 102 are aligned horizontally (e.g., aligned along the X direction and/or the Y direction). Similarly, the via interconnects (e.g., 301b, 301c, 301d, 301e) of the passive device 305 are aligned and/or extend horizontally (e.g., along the X direction and/or the Y direction), while the via interconnects of the substrate 102 are aligned and/or extend vertically (e.g., aligned along the Z direction). Thus, the via interconnects of the passive device 305 may be approximately orthogonal (e.g., approximately perpendicular) to the via interconnects of the substate 102. In some implementations, one by product of the design of the passive device 305 and the interconnects of the passive device 305, may be that a top portion (e.g., top surface) of the interconnects that define the inductor may not all be planar to each other, as illustrated by the conceptual plane 310. In some implementations, one by product of the design of the passive device 305 and the interconnects of the passive device 305, may be that a bottom portion (e.g., bottom surface) of the interconnects that define the inductor may not all be planar to each other, as illustrated by the conceptual plane 320. For example, a bottom surface (in the Z-direction) of the via interconnect 301d may not be planar to bottom surfaces (in the Z-direction) of the interconnect 202c and/or the interconnect 202d. In another example, a top surface (in the Z-direction) of the via interconnect 301e may not be planar to top surfaces (in the Z-direction) of the interconnect 202d and/or the interconnect 202e.

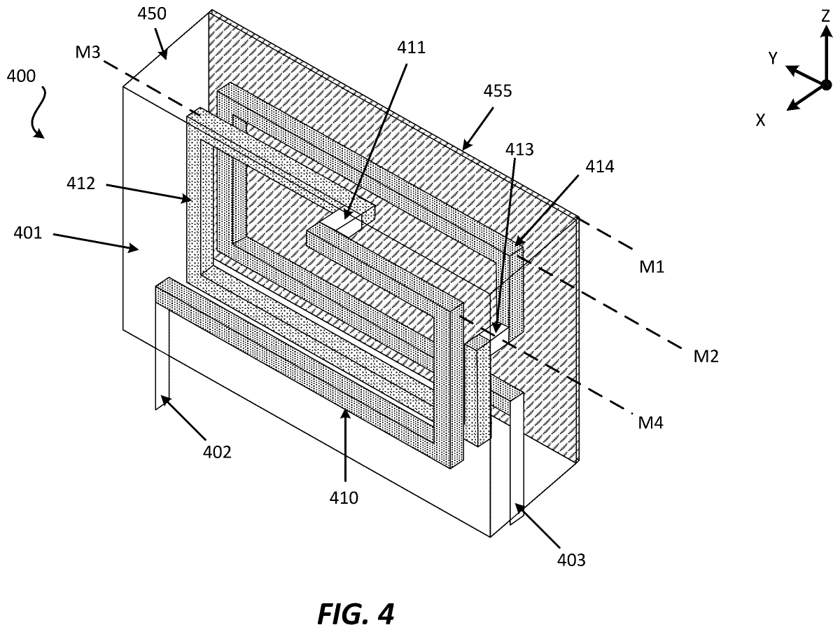

FIG. 4 illustrates angled view of a passive device 400 with vertically aligned interconnects. The passive device 400 may be a conceptually illustration of a passive device from the plurality of passive devices 105. The passive device 400 includes at least one dielectric layer 450, a plurality of interconnects 401 and a metal layer 455. The plurality of interconnects 401 may be configured as an inductor (e.g., solenoid inductor). The passive device 400 includes a terminal 402 and a terminal 403. The terminal 402 may be a first terminal of the inductor and/or the passive device 400. The terminal 403 may be a second terminal of the inductor and/or the passive device 400. The terminal 402 is coupled to the interconnect 410. The terminal 403 is coupled to the interconnect 414. The metal layer 455 is configured as an electromagnetic interference (EMI) shield.

The plurality of interconnects 401 includes an interconnect 410, a via interconnect 411, an interconnect 412, a via interconnect 413, and an interconnect 414. The plurality of interconnects 401 may define windings for the inductor (e.g., solenoid inductor). The interconnect 414 is located on a M2 metal layer of the passive device 400. The interconnect 412 is located on a M3 metal layer of the passive device 400. The interconnect 410 is located on a M4 metal layer of the passive device 400.

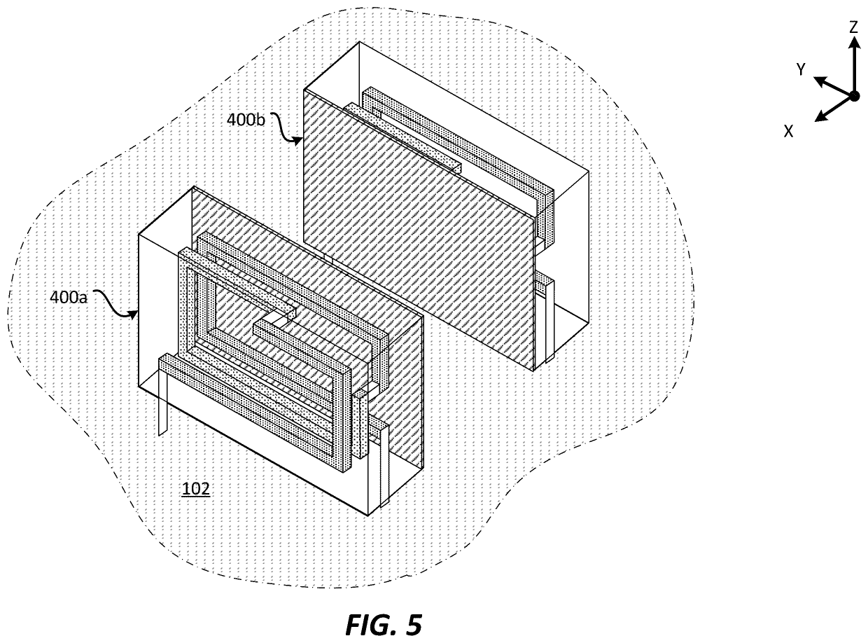

FIG. 5 illustrates an angled view of two passive devices that are adjacent to one another. The passive device 400a and the passive device 400b may be coupled to the substrate 102 through a plurality of solder interconnects (not shown). The passive device 400a includes a shield that is adjacent to the passive device 400b. The passive device 400b includes a shield that is adjacent to the passive device 400a.

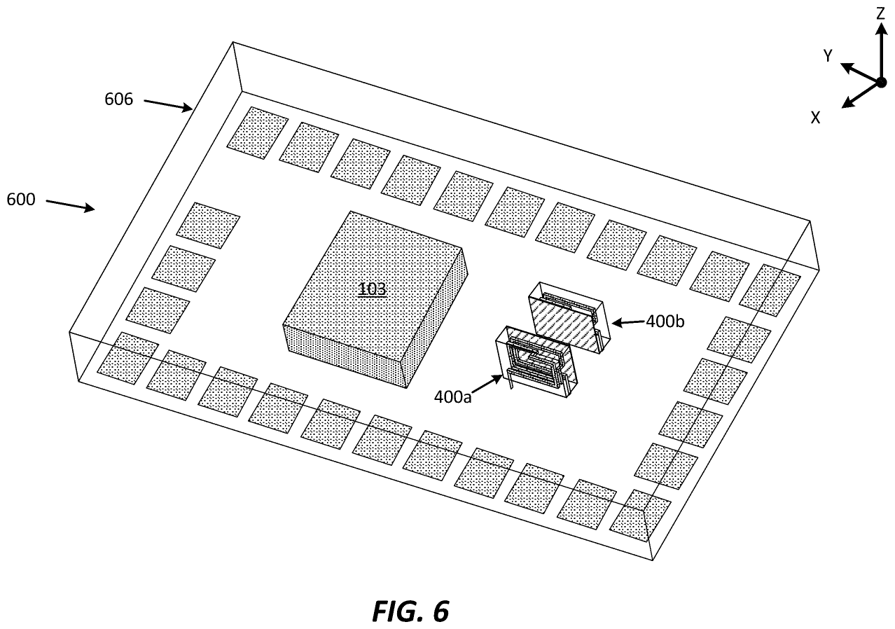

FIG. 6 illustrates an angled view of a package 600 that includes an integrated device 103, the passive device 400a, the passive device 400b and an encapsulation layer 606. FIG. 6 illustrates an example of how passive devices may be located in a package relative to an integrated device.

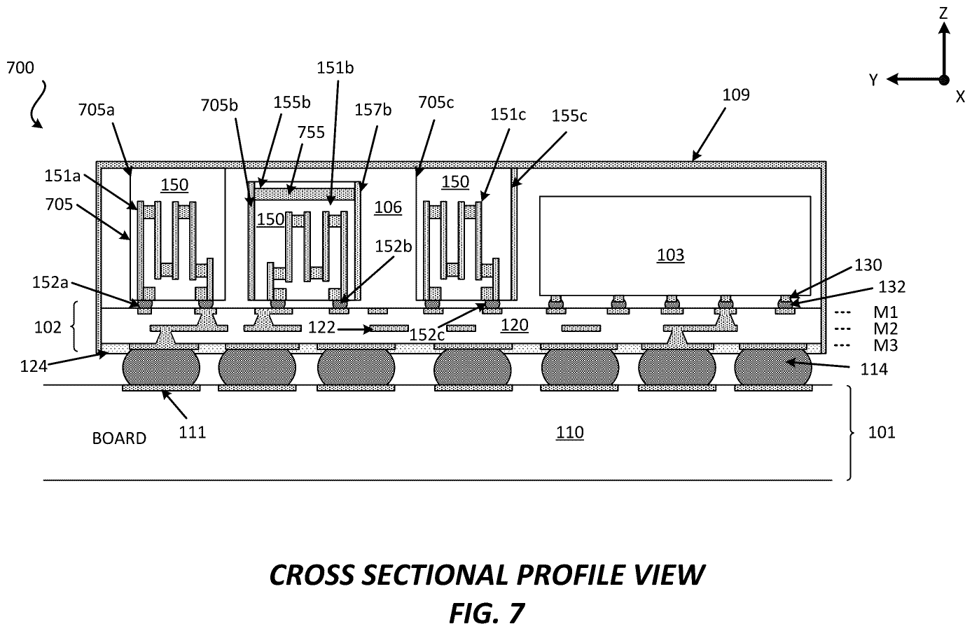

FIG. 7 illustrates a cross sectional profile view of a package 700 that includes a passive device with vertically aligned interconnects. The package 700 is similar to the package 100 of FIG. 1, and includes components that are configured in a similar manner as the package 100. The package 700 includes different configurations of the passive devices from the package 100.

The package 700 is coupled to a board 101 through a plurality of solder interconnects 114. The board 101 includes at least one board dielectric layer 110 and a plurality of board interconnects 112. The board 101 may include a printed circuit board (PCB). In some implementations, the package 700 may be coupled to a substrate instead of the board 101.

The package 700 includes a substrate 102, an integrated device 103, a plurality of passive devices 105, an encapsulation layer 106 and a metal layer 109. The plurality of passive devices 705 includes a passive device 705a, a passive device 705b and a passive device 705c. The passive device 705a may be configured as an inductor device. The passive device 705b may be configured as an inductor device. The passive device 705c may be configured as an inductor device.

The substrate 102 may be a laminated substrate (e.g., coreless substrate, cored substrate). The substrate 102 includes at least one dielectric layer 120, a plurality of interconnects 122 and a solder resist layer 124. The plurality of interconnects 122 may include a plurality of substrate interconnects (e.g., substrate trace interconnects, substrate pad interconnects, substrate via interconnects). Some of the interconnects from the plurality of interconnects 122 may be located on at least one metal layer (e.g., substrate metal layer) of the substrate 102. Substrate via interconnects of the plurality of interconnects 122, by definition, are not located on a metal layer of the substrate 102. Substrate via interconnects may be located between metal layers of the substrate 102. As shown in FIG. 7, the substrate 102 includes 3 substrate metal layers (e.g., M1, M2, M3). However, different implementations may have different numbers of substrate metal layers. As shown in FIG. 7. the substrate metal layers of the substrate 102 may be aligned in the X direction and/or the Y direction. The substrate metal layers of the substrate 102 may be aligned in a horizontal direction. The substrate metal layers of the substrate 102 may be located on an X-Y plane and/or parallel to an X-Y plane. Interconnects, such as substrate trace interconnects and/or substrate pad interconnects, that are located on the substrate metal layers of the substrate 102 may be located on an X-Y plane and/or parallel to an X-Y plane.

The integrated device 103 is coupled to the substrate 102. The integrated device 103 may be coupled to the plurality of interconnects 122 of the substrate 102 through a plurality of pillar interconnects 130 and/or a plurality of solder interconnects 132.

The passive device 705a is coupled to the substrate 102. The passive device 705a may be coupled to the plurality of interconnects 122 of the substrate 102 through a plurality of solder interconnects 152a. The passive device 705a includes at least one dielectric layer 150 and a plurality of interconnects 151a. Some of the interconnects from the plurality of interconnects 151a are configured to operate as an inductor (e.g., solenoid inductor). The passive device 705a may include vertically aligned interconnects. The passive device 705a includes interconnects that are located on metal layers. The metal layers of the passive device 705a are aligned in the Z-direction. That is, interconnects that are located on the metal layers of the passive device 705a are aligned in the Z-direction. The metal layers of the passive device 705a may be located on the X-Z plane and/or the Y-Z plane (or parallel to the X-Z plane and/or the Y-Z plane). In some implementations, the metal layers of the passive device 705a are approximately orthogonal (e.g., approximately perpendicular) to the substrate metal layers of the substrate 102. Trace interconnects and/or pad interconnects are examples of interconnects that are located on metal layers of the passive device 705a. Via interconnects of the plurality of interconnects 151a, by definition, are not located on a metal layer of the passive device 705a.

The passive device 705b is coupled to the substrate 102. The passive device 705b may be coupled to the plurality of interconnects 122 of the substrate 102 through a plurality of solder interconnects 152b. The passive device 705b includes at least one dielectric layer 150 and a plurality of interconnects 151b. Some of the interconnects from the plurality of interconnects 151b are configured to operate as an inductor (e.g., solenoid inductor). The passive device 705b may include vertically aligned interconnects. The passive device 705b includes interconnects that are located on metal layers. The metal layers of the passive device 705b are aligned in the Z-direction. That is, interconnects that are located on the metal layers of the passive device 705b are aligned in the Z-direction. The metal layers of the passive device 705b may be located on the X-Z plane and/or the Y-Z plane (or parallel to the X-Z plane and/or the Y-Z plane). In some implementations, the metal layers of the passive device 705b are approximately orthogonal (e.g., approximately perpendicular) to the substrate metal layers of the substrate 102. Trace interconnects and/or pad interconnects are examples of interconnects that are located on metal layers of the passive device 705b. Via interconnects of the plurality of interconnects 151b, by definition, are not located on a metal layer of the passive device 705b. The passive device 705b include a first metal layer 155b that is configured as an electromagnetic interference (EMI) shield and a second metal layer 157b that is configured as an electromagnetic interference (EMI) shield. The first metal layer 155b may be a first compartmental shield that extends in the Z-direction. The second metal layer 157b may be a second compartmental shield that extends in the Z-direction. The first metal layer 155b is located on the side of the passive device 705b that is adjacent to the passive device 105a. The second metal layer 157b is located on the side of the passive device 705b that is adjacent to the passive device 105c. The passive device 705b also includes a plurality of interconnects 755. The plurality of interconnects 755 may be a stack of via interconnects and/or a stack of pad interconnects. The plurality of interconnects 755 may be coupled to the first metal layer 155b and the second metal layer 157b. The plurality of interconnects 755 may be configured as an electromagnetic interference (EMI) shield.

The passive device 705c is coupled to the substrate 102. The passive device 705c may be coupled to the plurality of interconnects 122 of the substrate 102 through a plurality of solder interconnects 152c. The passive device 705c includes at least one dielectric layer 150 and a plurality of interconnects 151c. Some of the interconnects from the plurality of interconnects 151c are configured to operate as an inductor (e.g., solenoid inductor). The passive device 705c may include vertically aligned interconnects. The passive device 705c includes interconnects that are located on metal layers. The metal layers of the passive device 705c are aligned in the Z-direction. That is, interconnects that are located on the metal layers of the passive device 705c are aligned in the Z-direction. The metal layers of the passive device 705c may be located on the X-Z plane and/or the Y-Z plane (or parallel to the X-Z plane and/or the Y-Z plane). In some implementations, the metal layers of the passive device 705c are approximately orthogonal (e.g., approximately perpendicular) to the substrate metal layers of the substrate 102. Trace interconnects and/or pad interconnects are examples of interconnects that are located on metal layers of the passive device 705c. Via interconnects of the plurality of interconnects 151c, by definition, are not located on a metal layer of the passive device 705c. The passive device 705c include a metal layer 155c that is configured as an electromagnetic interference (EMI) shield. The metal layer 155c may be a compartmental shield that extends in the Z-direction. The metal layer 155c is located on the side of the passive device 705c that is adjacent to the integrated device 103. It is noted that the terms “orthogonal” and/or “perpendicular” may mean “approximately orthogonal” and/or “approximately perpendicular”. An object that is orthogonal and/or perpendicular to another object may mean that the object is offset and/or rotated by approximately 90 degrees relative to the another object. In some implementations, approximately 90 degrees may be mean in a range of about 85-95 degrees. However, approximately 90 degrees may mean other ranges and/or variances in degrees.

The encapsulation layer 106 is coupled to the substrate 102. The encapsulation layer 106 may at least partially encapsulate the integrated device 103, the passive device 705a, the passive device 705b and the passive device 705c. The encapsulation layer 106 may include a mold, a resin, an epoxy and/or a filler.

The metal layer 109 is coupled to a surface (e.g., top surface, side portion) of the encapsulation layer 160 and a side surface (e.g., side portion) of the substrate 102. The metal layer 109 may be configured as an electromagnetic interference (EMI) shield (e.g., EMI conformal shield). The metal layer 109 may be coupled to and touch the metal layer 155a of the passive device 705a and/or the metal layer 155c of the passive device 705c.

An integrated device (e.g., 103) may include a die (e.g., semiconductor bare die). The integrated device may include a power management integrated circuit (PMIC). The integrated device may include an application processor. The integrated device may include a modem. The integrated device may include a radio frequency (RF) device, a passive device, a filter, a capacitor, an inductor, an antenna, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. An integrated device may include at least one electronic circuit (e.g., first electronic circuit, second electronic circuit, etc . . . ). An integrated device may include an input/output (I/O) hub. An integrated device may include transistors. An integrated device may be an example of an electrical component and/or electrical device.

In some implementations, an integrated device may be a chiplet. A chiplet may be fabricated using a process that provides better yields compared to other processes used to fabricate other types of integrated devices, which can lower the overall cost of fabricating a chiplet. Different chiplets may have different sizes and/or shapes. Different chiplets may be configured to provide different functions. Different chiplets may have different interconnect densities (e.g., interconnects with different width and/or spacing). In some implementations, several chiplets may be used to perform the functionalities of one or more chips (e.g., one more integrated devices). As mentioned above, using several chiplets that perform several functions may reduce the overall cost of a package relative to using a single chip to perform all of the functions of a package. In some implementations, one or more of the chiplets and/or one of more of integrated devices (e.g., 103) described in the disclosure may be fabricated using the same technology node or two or more different technology nodes. For example, an integrated device may be fabricated using a first technology node, and a chiplet may be fabricated using a second technology node that is not as advanced as the first technology node. In such an example, the integrated device may include components (e.g., interconnects, transistors) that have a first minimum size, and the chiplet may include components (e.g., interconnects, transistors) that have a second minimum size, where the second minimum size is greater than the first minimum size. In some implementations, a first integrated device and a second integrated device of a package, may be fabricated using the same technology node or different technology nodes. In some implementations, a chiplet and another chiplet of a package, may be fabricated using the same technology node or different technology nodes.

A technology node may refer to a specific fabrication process and/or technology that is used to fabricate an integrated device and/or a chiplet. A technology node may specify the smallest possible size (e.g., minimum size) that can be fabricated (e.g., size of a transistor, width of trace, gap width between two transistors). Different technology nodes may have different yield loss. Different technology nodes may have different costs. Technology nodes that produce components (e.g., trace, transistors) with fine details are more expensive and may have higher yield loss, than a technology node that produces components (e.g., trace, transistors) with details that are less fine. Thus, more advanced technology nodes may be more expensive and may have higher yield loss, than less advanced technology nodes. When all of the functions of a package are implemented in single integrated devices, the same technology node is used to fabricate the entire integrated device, even if some of the functions of the integrated devices do not need to be fabricated using that particular technology node. Thus, the integrated device is locked into one technology node. To optimize the cost of a package, some of the functions can be implemented in different integrated devices and/or chiplets, where different integrated devices and/or chiplets may be fabricated using different technology nodes to reduce overall costs. For example, functions that require the use of the most advanced technology node may be implemented in an integrated device, and functions that can be implemented using a less advanced technology node can be implemented in another integrated device and/or one or more chiplets. One example, would be an integrated device, fabricated using a first technology node (e.g., most advanced technology node), that is configured to provide compute applications, and at least one chiplet, that is fabricated using a second technology node, that is configured to provide other functionalities, where the second technology node is not as costly as the first technology node, and where the second technology node fabricates components with minimum sizes that are greater than the minimum sizes of components fabricated using the first technology node. Examples of compute applications may include high performance computing and/or high performance processing, which may be achieved by fabricating and packing in as many transistors as possible in an integrated device, which is why an integrated device that is configured for compute applications may be fabricated using the most advanced technology node available, while other chiplets may be fabricated using less advanced technology nodes, since those chiplets may not require as many transistors to be fabricated in the chiplets. Thus, the combination of using different technology nodes (which may have different associated yield loss) for different integrated devices and/or chiplets, can reduce the overall cost of a package, compared to using a single integrated device to perform all the functions of the package.

Another advantage of splitting the functions into several integrated devices and/or chiplets, is that it allows improvements in the performance of the package without having to redesign every single integrated device and/or chiplet. For example, if a configuration of a package uses a first integrated device and a first chiplet, it may be possible to improve the performance of the package by changing the design of the first integrated device, while keeping the design of the first chiplet the same. Thus, the first chiplet could be reused with the improved and/or different configured first integrated device. This saves cost by not having to redesign the first chiplet, when packages with improved integrated devices are fabricated.

The package (e.g., 100, 700) may be implemented in a radio frequency (RF) package. The RF package may be a radio frequency front end (RFFE) package. A package (e.g., 100, 700) may be configured to provide Wireless Fidelity (WiFi) communication and/or cellular communication (e.g., 2G, 3G, 4G, 5G, 6G). The packages (e.g., 100, 700) may be configured to support Global System for Mobile (GSM) Communications, Universal Mobile Telecommunications System (UMTS), and/or Long-Term Evolution (LTE). The packages (e.g., 100, 700) may be configured to transmit and receive signals having different frequencies and/or communication protocols.

### Exemplary Sequence for Fabricating a Passive Device with Vertically Aligned Interconnects

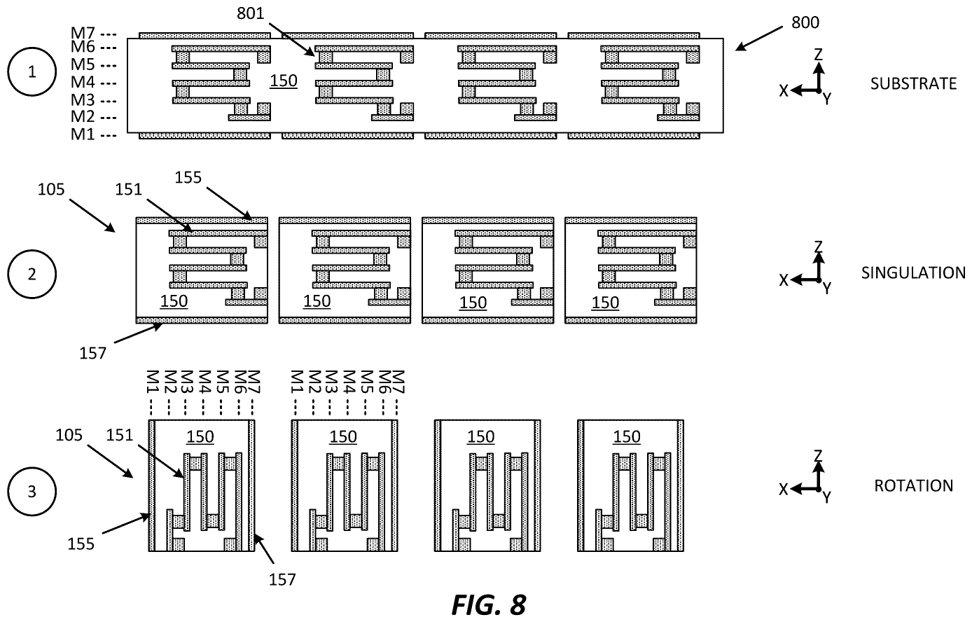

In some implementations, fabricating a passive device includes several processes. FIG. 8 illustrates an exemplary sequence for providing or fabricating a passive device. In some implementations, the sequence of FIG. 8 may be used to provide or fabricate the passive device from the plurality of passive devices 105. However, the process of FIG. 8 may be used to fabricate any of the passive devices described in the disclosure.

It should be noted that the sequence of FIG. 8 may combine one or more stages in order to simplify and/or clarify the sequence for providing or fabricating a package. In some implementations, the order of the processes may be changed or modified. In some implementations, one or more of processes may be replaced or substituted without departing from the scope of the disclosure.

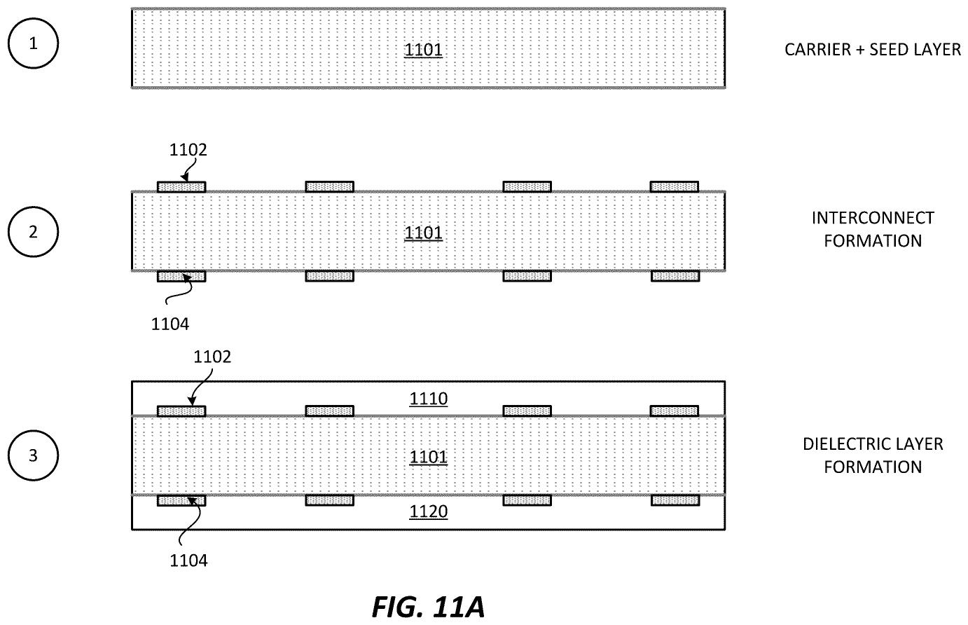

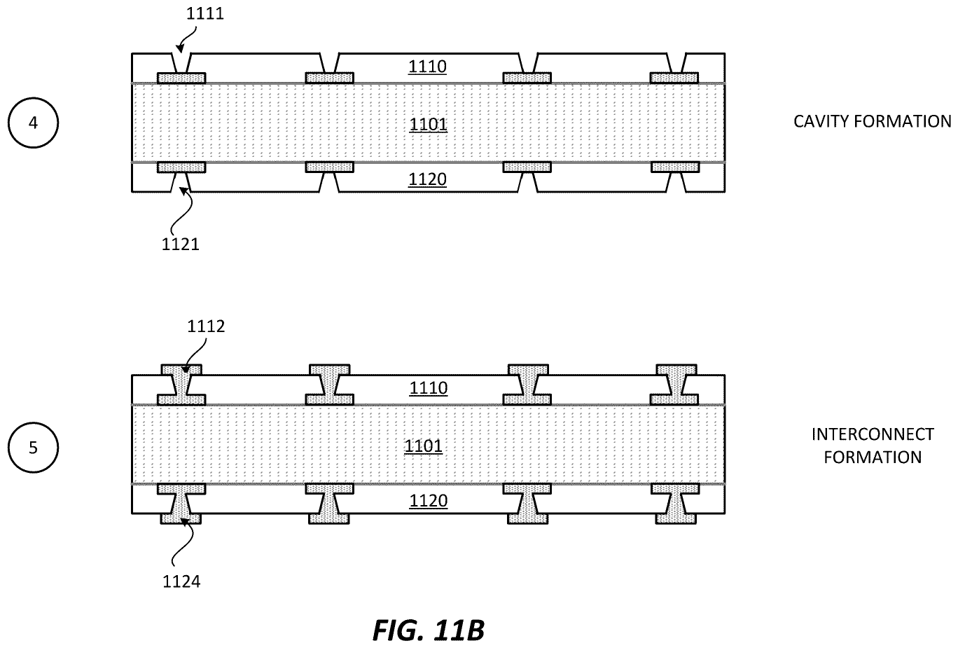

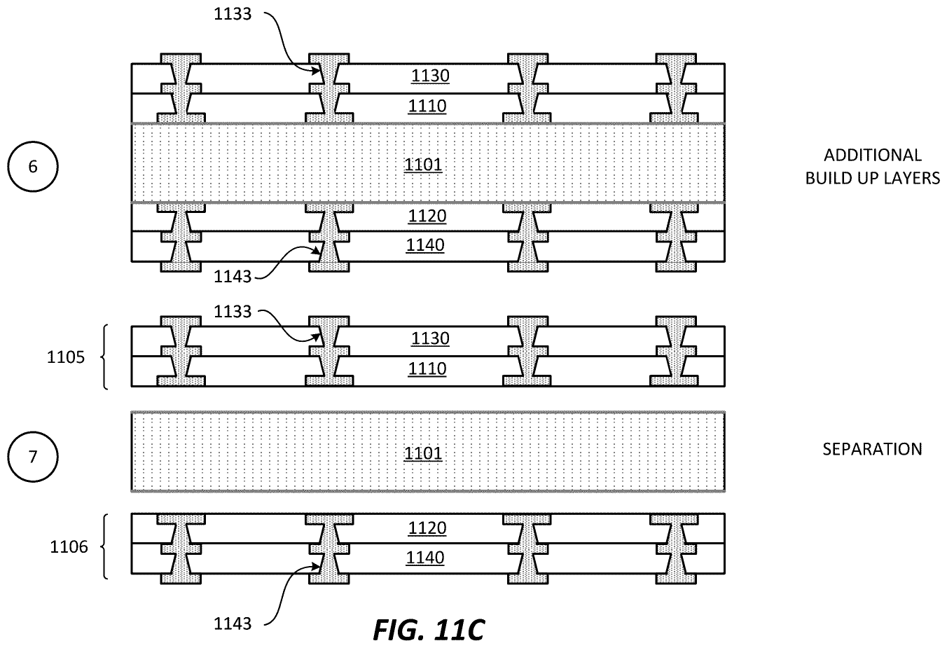

Stage 1, as shown in FIG. 8, illustrates a state after a substrate 800 is provided. The substrate 800 may include an organic substrate. The substrate 800 may include a laminated substrate. The substrate 800 includes at least one dielectric layer 150 and a plurality of interconnects 801. Some of the interconnects from the plurality of interconnects 801 may be configured to operate as an inductor. The substrate 800 includes several metal layers. Different implementations may have different numbers of metal layers. Some of the interconnects may be located on a metal layers. Some of the interconnects, such as via interconnects, may be located between metal layers. In some implementations, a thickness of interconnects on a metal layer is less than a thickness of via interconnects between metal layers. Thus, in some implementations, via interconnects may be thicker than the thickness of trace interconnects and/or pad interconnects on a metal layer. An example of a process for fabricating a substrate is described and illustrated below in at least FIGS. 11A-11C.

Stage 2 illustrates a state after singulation of the substrate 800 to form a plurality of passive devices 105. Each passive device from the plurality of passive devices 105 may include at least one dielectric layer 150, a plurality of interconnects 151, a metal layer 155 and a metal layer 157. Some interconnects from the plurality of interconnects 151 may be configured as an inductor (e.g., solenoid inductor). The metal layer 155 may be configured as an electromagnetic interference (EMI) shield. The metal layer 157 may be configured as an electromagnetic interference (EMI) shield. A mechanical process, such as a saw process, may be used to singulate the substrate 800 into the plurality of passive devices 105.

Stage 3 illustrates a state after passive devices from the plurality of passive devices 105 are rotated (e.g., rotated by approximately 90 degrees), such that the metal layers of the passive devices align in the Z direction (e.g., align in the vertical direction).

### Exemplary Sequence for Fabricating a Package Comprising a Passive Device with Vertically Aligned Interconnects

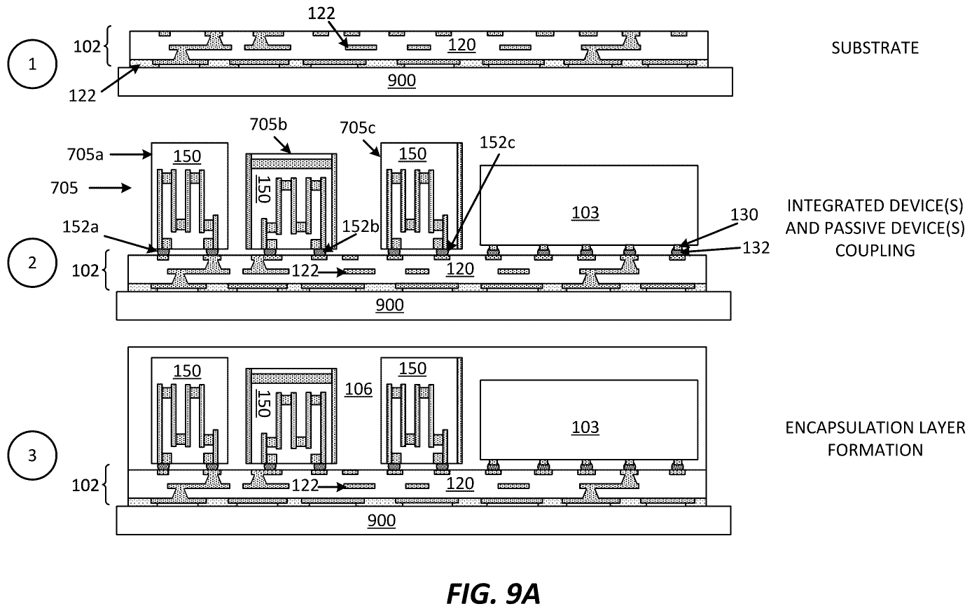

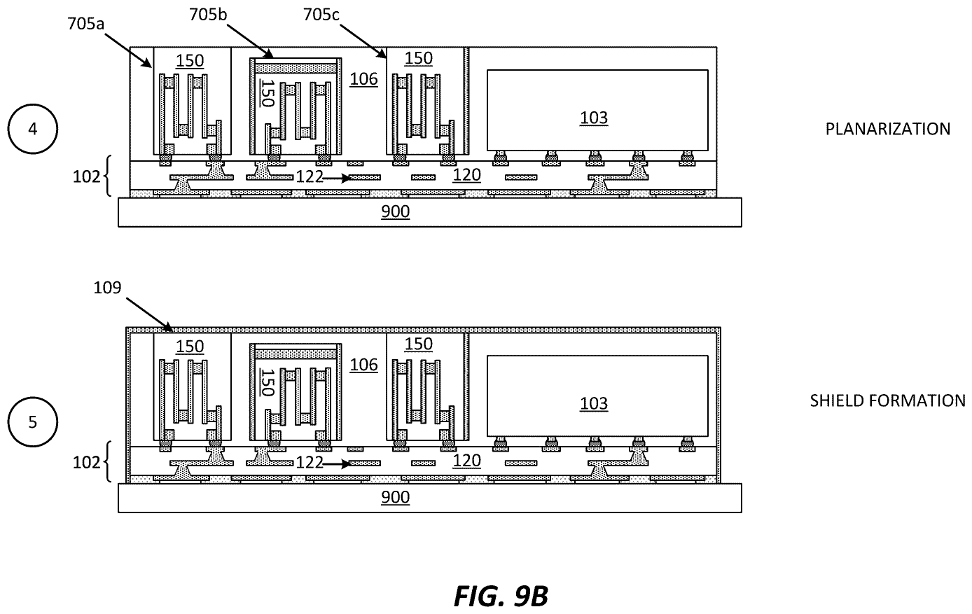

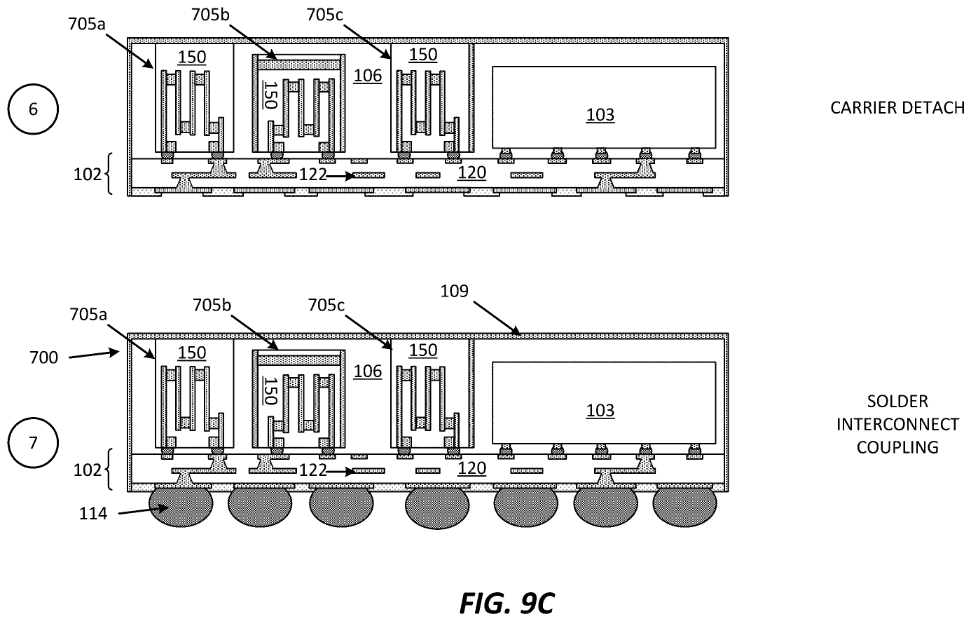

In some implementations, fabricating a package includes several processes. FIGS. 9A-9C illustrate an exemplary sequence for providing or fabricating a package. In some implementations, the sequence of FIGS. 9A-9C may be used to provide or fabricate the package 700. However, the process of FIGS. 9A-9C may be used to fabricate any of the packages described in the disclosure.

It should be noted that the sequence of FIGS. 9A-9C may combine one or more stages in order to simplify and/or clarify the sequence for providing or fabricating a package. In some implementations, the order of the processes may be changed or modified. In some implementations, one or more of processes may be replaced or substituted without departing from the scope of the disclosure.

Stage 1, as shown in FIG. 9A, illustrates a state after a substrate 102 is provided, placed and/or coupled to a carrier 900. The carrier 900 may be optional in some implementations. The carrier 900 may include glass. An adhesive may be used to place and couple the substrate 102 to the carrier 900. The substrate 102 may include at least one dielectric layer 120, a plurality of interconnects 122 and a solder resist layer 124. An example of a process for fabricating a substrate is described and illustrated below in at least FIGS. 11A-11C.

Stage 2 illustrates a state after the integrated device 103 and the plurality of passive devices 705 are placed and coupled to the substrate 102. The integrated device 103 is coupled to the plurality of interconnects 122 through a plurality of pillar interconnects 130 and/or a plurality of solder interconnects 132. The passive device 705a is coupled to the plurality of interconnects 122 through a plurality of solder interconnects 152a. The passive device 705b is coupled to the plurality of interconnects 122 through a plurality of solder interconnects 152b. The passive device 705c is coupled to the plurality of interconnects 122 through a plurality of solder interconnects 152c. A solder reflow process may be used to couple the integrated device 103 and/or the plurality of passive devices 705 to the substrate 102.

Stage 3 illustrates a state after an encapsulation layer 106 is provided and formed. The encapsulation layer 106 may include a mold, a resin, an epoxy and/or a filler. The encapsulation layer 106 may be provided by using a compression and transfer molding process, a sheet molding process, or a liquid molding process. The encapsulation layer 106 may be coupled to the substrate 102. The encapsulation layer 106 may at least partially encapsulate the integrated device 103, the passive device 705a, the passive device 705b and the passive device 705c. The encapsulation layer 706 may be over molded over the integrated device 103, the passive device 705a, the passive device 705b and the passive device 705c.

Stage 4, as shown in FIG. 9B, illustrates a state after the encapsulation layer 106 is planarized. Planarizing the encapsulation layer 106 may include removing portions of the encapsulation layer 106. Planarizing the encapsulation layer 106 may include removing portions of the passive device 705a, the passive device 705b and/or the passive device 705c. A grinding process may be used to planarize the encapsulation layer 106, the passive device 705a, the passive device 705b and/or the passive device 705c.

Stage 5 illustrates a state after a metal layer 109 is formed and coupled to a surface (e.g., top surface, side portion) of the encapsulation layer 106 and a side surface (e.g., side portion) of the substrate 102. A sputtering process may be used to form the metal layer 109. The metal layer 109 is configured as an electromagnetic interference (EMI) shield (e.g., conformal EMI shield). The metal layer 109 may be coupled to and touch the metal layer(s) of the passive devices. For example, the metal layer 109 may be coupled to and touch the metal layer 155c of the passive device 705c.

Stage 6, as shown in FIG. 9C, illustrates a state after the carrier 900 is decoupled from the substrate 102. The carrier 900 may be detached from the substrate 102.

Stage 7 illustrates a state after a plurality of solder interconnects 114 are coupled to the substrate 102. A solder reflow process may be used to couple the plurality of solder interconnects 114 to the plurality of interconnects 122 of the substrate 102. Stage 7 may illustrate an example of a package that includes passive devices with vertically aligned metal layers and/or vertically aligned interconnects (e.g., vertically aligned trace interconnects and/or vertically aligned pad interconnects).

### Exemplary Flow Diagram of a Method for Fabricating a Package Comprising a Passive Device with Vertically Aligned Interconnects

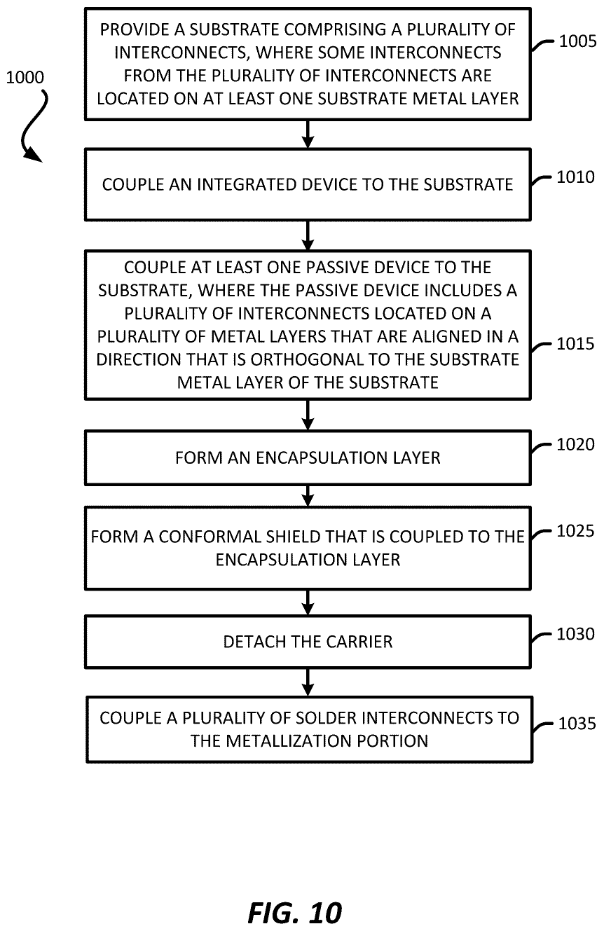

In some implementations, fabricating a package includes several processes. FIG. 10 illustrates an exemplary flow diagram of a method 1000 for providing or fabricating a package. In some implementations, the method 1000 of FIG. 10 may be used to provide or fabricate the package 700 described in the disclosure. However, the method 1000 may be used to provide or fabricate any of the packages described in the disclosure.

It should be noted that the method 1000 of FIG. 10 may combine one or more processes in order to simplify and/or clarify the method for providing or fabricating a package. In some implementations, the order of the processes may be changed or modified.

The method provides (at 1005) a substrate. The substrate includes at least one dielectric layer and a plurality of interconnects, where some of the interconnects are located on at least one substrate metal layer. The substrate may be coupled to a carrier. Stage 1 of FIG. 9A, illustrates and describes an example of a state after a substrate 102 is provided, placed and/or coupled to a carrier 900. The carrier 900 may be optional in some implementations. The carrier 900 may include glass. An adhesive may be used to place and couple the substrate 102 to the carrier 900. The substrate 102 may include at least one dielectric layer 120, a plurality of interconnects 122 and a solder resist layer 124. An example of a process for fabricating a substrate is described and illustrated below in at least FIGS. 11A-11B.

The method couples (at 1010) at least one integrated device to the substrate. The method also couples (at 1015) at least one passive device to the substrate, where the passive device includes a plurality of interconnects located on a plurality of metal layers that are aligned in a direction that is approximately orthogonal to the substrate metal layer of the substrate. Stage 2 of FIG. 9B, illustrates and describes an example of a state after the integrated device 103 and the plurality of passive devices 705 are placed and coupled to the substrate 102. The integrated device 103 is coupled to the plurality of interconnects 122 through a plurality of pillar interconnects 130 and/or a plurality of solder interconnects 132. The passive device 705a is coupled to the plurality of interconnects 122 through a plurality of solder interconnects 152a. The passive device 705b is coupled to the plurality of interconnects 122 through a plurality of solder interconnects 152b. The passive device 705c is coupled to the plurality of interconnects 122 through a plurality of solder interconnects 152c. A solder reflow process may be used to couple the integrated device 103 and/or the plurality of passive devices 705 to the substrate 102.

The method forms (at 1020) an encapsulation layer that at least partially encapsulates the passive device(s) and the integrated device(s). Stage 3 of FIG. 9A, illustrates and describes an example of a state after an encapsulation layer 106 is provided and formed. The encapsulation layer 106 may include a mold, a resin, an epoxy and/or a filler. The encapsulation layer 106 may be provided by using a compression and transfer molding process, a sheet molding process, or a liquid molding process. The encapsulation layer 106 may be coupled to the substrate 102. The encapsulation layer 106 may at least partially encapsulate the integrated device 103, the passive device 705a, the passive device 705b and the passive device 705c. The encapsulation layer 706 may be over molded over the integrated device 103, the passive device 705a, the passive device 705b and the passive device 705c.

In some implementations, forming an encapsulation layer may also including planarizing the encapsulation layer. Stage 4 of FIG. 9B, illustrates and describes an example of a state after the encapsulation layer 106 is planarized. Planarizing the encapsulation layer 106 may include removing portions of the encapsulation layer 106. Planarizing the encapsulation layer 106 may include removing portions of the passive device 705a, the passive device 705b and/or the passive device 705c. A grinding process may be used to planarize the encapsulation layer 106, the passive device 705a, the passive device 705b and/or the passive device 705c.

The method forms (at 1025) a conformal shield that is coupled to a surface of the encapsulation layer. Stage 5 of FIG. 9B, illustrates and describes an example of a state after a metal layer 109 is formed and coupled to a surface of the encapsulation layer 106 and a side surface of the substrate 102. A sputtering process may be used to form the metal layer 109. The metal layer 109 is configured as an electromagnetic interference (EMI) shield (e.g., conformal EMI shield). The metal layer 109 may be coupled to and touch the metal layer(s) of the passive devices. For example, the metal layer 109 may be coupled to and touch the metal layer 155c of the passive device 705c.

The method detaches (at 1030) the carrier. Stage 6 of FIG. 9C, illustrates and describes an example of a state after the carrier 900 is decoupled from the substrate 102. The carrier 900 may be detached from the substrate 102.

The method couples (at 1035) a plurality of solder interconnects to the substrate. Stage 7 of FIG. 9C, illustrates and describes an example of a state after a plurality of solder interconnects 114 are coupled to the substrate 102. A solder reflow process may be used to couple the plurality of solder interconnects 114 to the plurality of interconnects 122 of the substrate 102. Stage 7 may illustrate an example of a package that includes passive devices with vertically aligned interconnects (e.g., vertically aligned trace interconnects and/or vertically aligned pad interconnects).

### Exemplary Sequence for Fabricating a Substrate

In some implementations, fabricating a substrate includes several processes. FIGS. 11A-11C illustrate an exemplary sequence for providing or fabricating a substrate. In some implementations, the sequence of FIGS. 11A-11C may be used to provide or fabricate a laminated substrate. For example, the sequence of FIGS. 11A-11C may be used to provide or fabricate the substrate 102.

It should be noted that the sequence of FIGS. 11A-11C may combine one or more stages in order to simplify and/or clarify the sequence for providing or fabricating a substrate. In some implementations, the order of the processes may be changed or modified. In some implementations, one or more of processes may be replaced or substituted without departing from the scope of the disclosure.

Stage 1, as shown in FIG. 11A, illustrates a state after a carrier 1101 is provided. The carrier 1101 may include a core layer. The core layer may include seed layers on surfaces of the core layer.

Stage 2 illustrates a state after a plurality of interconnects 1102 and a plurality of interconnects 1104 are formed. The plurality of interconnects 1102 may be coupled to a first surface (e.g., top surface) of the carrier 1101. The plurality of interconnects 1104 may be coupled to a second surface (e.g., bottom surface) of the carrier 1101. A plating process may be used to form the plurality of interconnects 1102 and the plurality of interconnects 1104. The plurality of interconnects 1102 may be formed on a first seed layer of the carrier 1101. The plurality of interconnects 1104 may be formed on a second seed layer of the carrier 1101.

Stage 3 illustrates a state after a dielectric layer 1110 and a dielectric layer 1120 are provided. The dielectric layer 1110 may be coupled to the first surface of the carrier 1101. The dielectric layer 1120 may be coupled to the second surface of the carrier 1101. A deposition and/or a lamination process may be used to form the dielectric layer 1110 and/or the dielectric layer 1120. The dielectric layer 1110 and/or the dielectric layer 1120 may include prepreg, polymer and/or Ajinomoto Build-up Film (ABF).

Stage 4 of FIG. 11B, illustrates a state after a plurality of cavities 1111 are formed in the dielectric layer 1110, and a plurality of cavities 1121 are formed in the dielectric layer 1120. An exposure and development process may be used to form the plurality of cavities 1111 in the dielectric layer 1110 and the plurality of cavities 1121 in the dielectric layer 1120. Different implementations may use different processes to form the plurality of cavities.

Stage 5 illustrates a state after a plurality of interconnects 1112 are formed in the dielectric layer 1110, and a plurality of interconnects 1124 are formed in the dielectric layer 1120. The plurality of interconnects 1112 may be coupled to the plurality of interconnects 1102. The plurality of interconnects 1124 may be coupled to the plurality of interconnects 1104. A plating process may be used to form the plurality of interconnects 1112 and/or the plurality of interconnects 1124.

Stage 6, as shown in FIG. 11C, illustrates a state after additional build up layers are formed. For example, stage 6 illustrates a state after additional dielectric layers and additional interconnects are formed. For example, a dielectric layer 1130 may be formed and coupled to the dielectric layer 1110. A dielectric layer 1140 may be formed and coupled to the dielectric layer 1120. A lamination process and/or a deposition process may be used to form the dielectric layer 1130 and the dielectric layer 1140.

Stage 6 further illustrates a state after a plurality of interconnects 1133 are formed in and over the dielectric layer 1130, and after a plurality of interconnects 1143 are formed in and over the dielectric layer 1140. The plurality of interconnects 1133 may be coupled to the plurality of interconnects 1112. The plurality of interconnects 1143 may be coupled to the plurality of interconnects 1124. A plurality of cavities may be formed in the dielectric layer 1130 and the dielectric layer 1140 in a similar manner as described for forming a plurality of cavities in Stage 4 of FIG. 11B. The plurality of interconnects 1133 and the plurality of interconnects 1143 may be formed in a similar manner as described for fabricating a plurality of interconnects in Stage 5 of FIG. 11B.

Stage 7 illustrates a state after separation of the dielectric layers from the carrier 1101. For example, the dielectric layer 1110, the dielectric layer 1130, the plurality of interconnects 1102, the plurality of interconnects 1112 and the plurality of interconnects 1133 are separated from the carrier 1101 to form a substrate 1105 (e.g., coreless substrate). In another example, the dielectric layer 1120, the dielectric layer 1140, the plurality of interconnects 1104, the plurality of interconnects 1124 and the plurality of interconnects 1143 are separated from the carrier 1101 to form a substrate 1106 (e.g., coreless substrate).

The substrate 1105 and/or the substrate 1106 may be used instead of the substrate 102, in the package 100 and/or the package 700. In some implementations, once separation occurs, one or more solder resist layers may be formed on surface(s) of the substrate 1105 and/or the substrate 1106. In some implementations, the solder resist layer(s) may be a polyimide dielectric layer.

### Exemplary Flow Diagram of a Method for Fabricating a Substrate

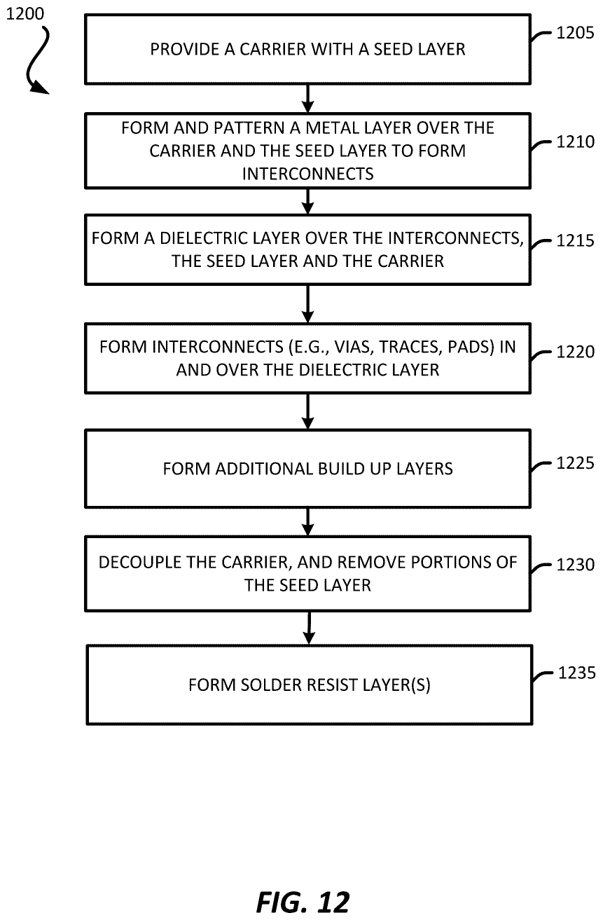

In some implementations, fabricating an substrate includes several processes. FIG. 12 illustrates an exemplary flow diagram of a method 1200 for providing or fabricating a substrate. In some implementations, the method 1200 of FIG. 12 may be used to provide or fabricate the substrate 102.

It should be noted that the method 1200 of FIG. 12 may combine one or more processes in order to simplify and/or clarify the method for providing or fabricating a substrate. In some implementations, the order of the processes may be changed or modified.

The method provides (at 1205) a carrier. The carrier may include seed layers. Stage 1 of FIG. 11A, illustrates and describes an example of a state after a carrier 1101 is provided. The carrier 1101 may include a core layer. The core layer may include seed layers on surfaces of the core layer.

The method forms (at 1210) a plurality of interconnects on the carrier and/or the seed layer(s). Stage 2 of FIG. 11A, illustrates and describes an example of a state after a plurality of interconnects 1102 and a plurality of interconnects 1104 are formed. The plurality of interconnects 1102 may be coupled to a first surface (e.g., top surface) of the carrier 1101. The plurality of interconnects 1104 may be coupled to a second surface (e.g., bottom surface) of the carrier 1101. A plating process may be used to form the plurality of interconnects 1102 and the plurality of interconnects 1104. The plurality of interconnects 1102 may be formed on a first seed layer of the carrier 1101. The plurality of interconnects 1104 may be formed on a second seed layer of the carrier 1101.

The method forms (at 1215) at least one dielectric layer over the plurality of interconnects, the seed layer(s) and/or the carrier. Stage 3 of FIG. 11A, illustrates and describes an example of a state after a dielectric layer 1110 and a dielectric layer 1120 are provided. The dielectric layer 1110 may be coupled to the first surface of the carrier 1101. The dielectric layer 1120 may be coupled to the second surface of the carrier 1101. A deposition and/or a lamination process may be used to form the dielectric layer 1110 and/or the dielectric layer 1120. The dielectric layer 1110 and/or the dielectric layer 1120 may include prepreg, polymer and/or Ajinomoto Build-up Film (ABF).

Forming the plurality of interconnects may include forming a plurality of cavities in the dielectric layer(s). Stage 4 of FIG. 11B, illustrates and describes an example of a state after a plurality of cavities 1111 are formed in the dielectric layer 1110, and a plurality of cavities 1121 are formed in the dielectric layer 1120. An exposure and development process may be used to form the plurality of cavities 1111 in the dielectric layer 1110 and the plurality of cavities 1121 in the dielectric layer 1120. Different implementations may use different processes to form the plurality of cavities.

Stage 5 of FIG. 11B, illustrates and describes an example of a state after a plurality of interconnects 1112 are formed in the dielectric layer 1110, and a plurality of interconnects 1124 are formed in the dielectric layer 1120. The plurality of interconnects 1112 may be coupled to the plurality of interconnects 1102. The plurality of interconnects 1124 may be coupled to the plurality of interconnects 1104. A plating process may be used to form the plurality of interconnects 1112 and/or the plurality of interconnects 1124.

The method forms (at 1225) additional build up layers. Stage 6 of FIG. 11C, illustrates and describes an example of a state after additional build up layers are formed. For example, stage 6 illustrates a state after additional dielectric layers and additional interconnects are formed. For example, a dielectric layer 1130 may be formed and coupled to the dielectric layer 1110. A dielectric layer 1140 may be formed and coupled to the dielectric layer 1120. A lamination process and/or a deposition process may be used to form the dielectric layer 1130 and the dielectric layer 1140.

Stage 6 of FIG. 11C, further illustrates and describes an example of a state after a plurality of interconnects 1133 are formed in and over the dielectric layer 1130, and after a plurality of interconnects 1143 are formed in and over the dielectric layer 1140. The plurality of interconnects 1133 may be coupled to the plurality of interconnects 1112. The plurality of interconnects 1143 may be coupled to the plurality of interconnects 1124. A plurality of cavities may be formed in the dielectric layer 1130 and the dielectric layer 1140 in a similar manner as described for forming a plurality of cavities in Stage 4 of FIG. 11B. The plurality of interconnects 1133 and the plurality of interconnects 1143 may be formed in a similar manner as described for fabricating a plurality of interconnects in Stage 5 of FIG. 11B.

The method decouples (at 1230) the carrier from the dielectric layers. The method may further remove portions of the seed layer(s). Stage 7 of FIG. 11C, illustrates and describes an example of a state after separation of the dielectric layers from the carrier 1101. For example, the dielectric layer 1110, the dielectric layer 1130, the plurality of interconnects 1102, the plurality of interconnects 1112 and the plurality of interconnects 1133 are separated from the carrier 1101 to form a substrate 1105 (e.g., coreless substrate). In another example, the dielectric layer 1120, the dielectric layer 1140, the plurality of interconnects 1104, the plurality of interconnects 1124 and the plurality of interconnects 1143 are separated from the carrier 1101 to form a substrate 1106 (e.g., coreless substrate). The substrate 1105 and/or the substrate 1106 may be used instead of the substrate 102, in the package 100 and/or the package 700.

The method may further form (at 1235) solder resist layer(s) on the substrate. In some implementations, once separation occurs, one or more solder resist layers may be formed on surface(s) of the substrate 1105 and/or the substrate 1106. In some implementations, the solder resist layers may be a polyimide dielectric layer.

### Exemplary Electronic Devices

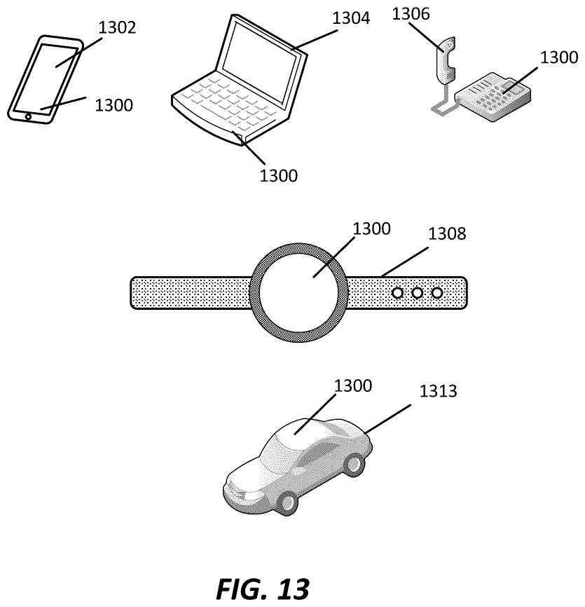

FIG. 13 illustrates various electronic devices that may be integrated with any of the aforementioned device, integrated device, integrated circuit (IC) package, integrated circuit (IC) device, semiconductor device, integrated circuit, die, interposer, package, package-on-package (PoP), System in Package (SiP), or System on Chip (SoC). For example, a mobile phone device 1302, a laptop computer device 1304, a fixed location terminal device 1306, a wearable device 1308, or automotive vehicle 1310 may include a device 1300 as described herein. The device 1300 may be, for example, any of the devices and/or integrated circuit (IC) packages described herein. The devices 1302, 1304, 1306 and 1308 and the vehicle 1310 illustrated in FIG. 13 are merely exemplary. Other electronic devices may also feature the device 1300 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 1-8, 9A-9C, 10, 11A-11C and 12-13 may be rearranged and/or combined into a single component, process, feature or function or embodied in several components, processes, or functions. Additional elements, components, processes, and/or functions may also be added without departing from the disclosure. It should also be noted FIGS. 1-8, 9A-9C, 10, 11A-11C and 12-13 and its corresponding description in the present disclosure is not limited to dies and/or ICs. In some implementations, FIGS. 1-8, 9A-9C, 10, 11A-11C and 12-13 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (PoP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another—even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The terms “encapsulate”, “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace (e.g., trace interconnect), a via (e.g., via interconnect), a pad (e.g., pad interconnect), a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the invention.

Aspect 1: A package comprising a substrate comprising a plurality of substrate interconnects, wherein some substrate interconnects from the substrate interconnects are located on at least one substrate metal layer; an integrated device coupled to the substrate; and a passive device coupled to the substrate, wherein the passive device comprises: at least one dielectric layer; and a plurality of interconnects, wherein the plurality of interconnects comprise a first plurality of interconnects that are located on a plurality of metal layers, and wherein the plurality of metal layers are aligned in a direction that is orthogonal to the at least one substrate metal layer of the substrate; and an encapsulation layer that at least partially encapsulates the integrated device and the passive device.

Aspect 2: The package of aspect 1, wherein the passive device is configured as an inductor.

Aspect 3: The package of aspects 1 through 2, wherein the plurality of interconnects further comprise a plurality of via interconnects that are located between metal layers from the plurality of metal layers.

Aspect 4: The package of aspects 1 through 3, wherein the passive device further comprises a first metal layer configured as a first shield.

Aspect 5: The package of aspect 4, wherein the passive device further comprises a second metal layer configured as a second shield.

Aspect 6: The package of aspect 4, further comprising a metal layer coupled to the encapsulation layer, wherein the metal layer is configured as an electromagnetic interference (EMI) shield.

Aspect 7: The package of aspect 6, wherein the metal layer is coupled to a side portion of the encapsulation layer.

Aspect 8: The package of aspects 1 through 7, wherein the first plurality of interconnects include trace interconnects and/or pad interconnects.

Aspect 9: The package of aspect 8, wherein the first plurality of interconnects do not include via interconnects.

Aspect 10: The package of aspect 9, wherein the via interconnects from the passive device are located between metal layers of the passive device.

Aspect 11: The package of aspects 1 through 10, wherein the encapsulation layer includes a material that is different from the at least one dielectric layer of the passive device.

Aspect 12: The package of aspects 1 through 11, wherein the passive device is coupled to the substrate through a plurality of solder interconnects.

Aspect 13: The package of aspects 1 through 12, wherein the integrated device is coupled to the substrate through a plurality of pillar interconnects and/or a plurality of solder interconnects.

Aspect 14: The package of aspects 1 through 13, wherein the package further comprises a second passive device coupled to the substrate, wherein the second passive device comprises at least one second dielectric layer; and a second plurality of interconnects, wherein the second plurality of interconnects comprise a third plurality of interconnects that are located on a first plurality of metal layers, and wherein the first plurality of metal layers are aligned in a direction that is orthogonal to the at least one substrate metal layer of the substrate.

Aspect 15: The package of aspect 14, wherein the second passive device further comprises a first metal layer configured as a first shield.

Aspect 16: The package of aspect 15, wherein the first shield is adjacent to the integrated device.

Aspect 17: The package of aspect 15, wherein the first shield is adjacent to the passive device.

Aspect 18: The package of aspects 1 through 17, wherein the plurality of metal layers are aligned in a Z direction, and the at least one substrate metal layer of the substrate is aligned in a X direction and/or Y direction.

Aspect 19: The package of aspects 1 through 17, wherein the plurality of metal layers are on a X-Z plane and/or a Y-Z plane, and the at least one substrate metal layer of the substrate is on a X-Y plane.

Aspect 20: The package of aspects 1 through 19, wherein the package is incorporated in a device from a group consisting one of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. A package comprising:
a substrate comprising a plurality of substrate interconnects, wherein some substrate interconnects from the substrate interconnects are located on at least one substrate metal layer;
an integrated device coupled to the substrate; and
a passive device coupled to the substrate, wherein the passive device comprises:
at least one dielectric layer; and
a plurality of interconnects, wherein the plurality of interconnects comprise a first plurality of interconnects that are located on a plurality of metal layers, and
wherein the plurality of metal layers are aligned in a direction that is orthogonal to the at least one substrate metal layer of the substrate; and
an encapsulation layer that at least partially encapsulates the integrated device and the passive device.

2. The package of claim 1, wherein the passive device is configured as an inductor.

3. The package of claim 1, wherein the plurality of interconnects further comprise a plurality of via interconnects that are located between metal layers from the plurality of metal layers.

4. The package of claim 1, wherein the passive device further comprises a first metal layer configured as a first shield.

5. The package of claim 4, wherein the passive device further comprises a second metal layer configured as a second shield.

6. The package of claim 4, further comprising a metal layer coupled to the encapsulation layer, wherein the metal layer is configured as an electromagnetic interference (EMI) shield.

7. The package of claim 6, wherein the metal layer is coupled to a side portion of the encapsulation layer.

8. The package of claim 1, wherein the first plurality of interconnects include trace interconnects and/or pad interconnects.

9. The package of claim 8, wherein the first plurality of interconnects do not include via interconnects.

10. The package of claim 9, wherein the via interconnects from the passive device are located between metal layers of the passive device.

11. The package of claim 1, wherein the encapsulation layer includes a material that is different from the at least one dielectric layer of the passive device.

12. The package of claim 1, wherein the passive device is coupled to the substrate through a plurality of solder interconnects.

13. The package of claim 1, wherein the integrated device is coupled to the substrate through a plurality of pillar interconnects and/or a plurality of solder interconnects.

14. The package of claim 1, wherein the package further comprises a second passive device coupled to the substrate, wherein the second passive device comprises:
at least one second dielectric layer; and
a second plurality of interconnects, wherein the second plurality of interconnects comprise a third plurality of interconnects that are located on a first plurality of metal layers, and
wherein the first plurality of metal layers are aligned in a direction that is orthogonal to the at least one substrate metal layer of the substrate.

15. The package of claim 14, wherein the second passive device further comprises a first metal layer configured as a first shield.

16. The package of claim 15, wherein the first shield is adjacent to the integrated device.

17. The package of claim 15, wherein the first shield is adjacent to the passive device.

18. The package of claim 1, wherein the plurality of metal layers are aligned in a Z direction, and the at least one substrate metal layer of the substrate is aligned in a X direction and/or Y direction.

19. The package of claim 1, wherein the plurality of metal layers are on a X-Z plane and/or a Y-Z plane, and the at least one substrate metal layer of the substrate is on a X-Y plane.

20. The package of claim 1, wherein the package is incorporated in a device from a group consisting one of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.
